(19) United States
(12) Patent Application Publication
(10) Pub. No.: US 2024/0063608 A1
(43) Pub. Date: Feb. 22, 2024

(54) MICRO VCSEL WITH IMPROVED BEAM QUALITY AND MICRO VCSEL ARRAY

(71) Applicant: Korea Photonics Technology Institute, Gwangju (KR)

(72) Inventors: Keon Hwa LEE, Gwangju (KR); Young Hee CHOI, Gwangju (KR)

(73) Assignee: Korea Photonics Technology Institute, Gwangju (KR)

(21) Appl. No.: 18/232,922

(22) Filed: Aug. 11, 2023

(30) Foreign Application Priority Data
Aug. 17, 2022 (KR) 10-2022-0102605
Aug. 17, 2022 (KR) 10-2022-0102612

(51) Int. Cl. H01S 5/183; H01S 5/32

(52) U.S. Cl. CPC H01S 5/18377; H01S 5/3216; H01S 5/18347; H01S 2301/176

(57) ABSTRACT

Disclosed are a micro VCSEL with improved beam quality and a micro VCSEL array. An embodiment of the present invention provides a micro VCSEL with improved beam quality of light or laser to be oscillated and a micro VCSEL array capable of improving manufacturing efficiency and minimizing efficiency degradation due to errors occurring during a transfer.

### CROSS-REFERENCE TO RELATED APPLICATIONS

This application claims priority to Korean Patent Application No. 10-2022-0102605 filed on 2022 Aug. 17 and Korean Patent Application No. 10-2022-0102612 filed on 2022 Aug. 17, the entire contents of which are herein incorporated by reference.

This patent is the results of research that was carried out by the support (a unique project number: 1415185090, a detailed project number: 20018154, a project name: Development of Multi-Axis Assembly System for Curved Free-Form Electronics) of Korea Evaluation Institute of Industrial Technology by the finances of the government of the Republic of Korea (Ministry of Trade, Industry and Energy) in 2023.

This patent is the results of research that was carried out by the support (a detailed project number: 20016532, a project name: Development of the system semiconductor package for augmented reality capable of detecting high-speed 3D image based on Vertical-cavity surface-emitting laser) of Korea Evaluation Institute of Industrial Technology by the finances of the government of the Republic of Korea (Ministry of Trade, Industry and Energy) in 2023.

### BACKGROUND

### 1. Field

The present invention relates to a micro VCSEL with improved beam quality of light or laser to be oscillated and a micro VCSEL array.

### 2. Description of Related Art

The content described in this section merely provides background information for an embodiment of the present invention and does not constitute the related art.

In general, a semiconductor laser diode includes an edge emitting laser diode (hereinafter abbreviated as ‘EEL’) and a vertical cavity surface emitting laser (hereinafter abbreviated as ‘VCSEL’). Since the EEL has a resonant structure in a direction parallel to a stacked surface of a device, a laser beam is oscillated in a direction parallel to the stacked surface. The VCSEL has a resonant structure in a direction perpendicular to the stacked surface of the device to oscillate a laser beam in the direction perpendicular to the stacked surface of the device.

Compared to the EEL, the VCSEL has a shorter optical gain length, enabling low-power implementation and high-density integration, which is advantageous for mass production. In addition, the VCSEL can oscillate a laser beam in a single longitudinal mode, and can be tested on a wafer. Moreover, the VCSEL is capable of high-speed modulation and may oscillate a circular beam. Accordingly, the VCSEL may be easily coupled with an optical fiber and implemented as a two-dimensional surface array.

The VCSEL has been mainly used as light sources in optical devices in optical communication, optical interconnection, optical pickup, and the like. Recently, however, the range of use of the VCSEL has been expanded to light sources in image forming devices such as LiDAR, face recognition, motion recognition, and augmented reality (AR) or virtual reality (VR) devices. As such, the VCSEL is used in various fields, and it is necessary to appropriately manufacture a VCSEL chip or a VCSEL array according to applications.

Typically, a VCSEL micro array is manufactured by manufacturing a VCSEL chip in a separate process, and transferring the manufactured VCSEL chip to a substrate. However, as a shift inevitably occurs in x, y, and el directions during the transfer, manufacturing and process efficiency is degraded in the conventional VCSEL array. In particular, when the sizes of the VCSEL chip and array are reduced to the order of several tens of μm, the VCSEL chip and array become more sensitive to such errors, and these errors greatly adversely affect the operation of the VCSEL chip and array.

### SUMMARY

An embodiment of the present invention provides a micro VCSEL with improved beam quality of light or laser to be oscillated and a micro VCSEL array capable of improving manufacturing efficiency and minimizing efficiency degradation due to errors occurring during a transfer.

According to an embodiment of the present invention, a micro VCSEL chip includes a first reflector including a plurality of distributed Bragg reflector (DBR) pairs, a second reflector including a plurality of DBR pairs, a multiple quantum well layer positioned between the first reflector and the second reflector and recombining holes generated from one of the first reflector and the second reflector and electrons generated from the other of the first reflector and the second reflector, a contact layer formed within one DBR pair of the second reflector, a first metal layer contacting the first reflector and supplying power to the first reflector, a second metal layer contacting the contact layer and supplying power to the second reflector, and a passivation layer protecting the first reflector, the second reflector, the multiple quantum well layer, the oxide film layer, and the contact layer from an outside, in which the contact layer has a mesa structure only on one side of the micro VCSEL chip.

The micro VCSEL chip may be implemented as a cross section of a predetermined shape.

The predetermined shape may be a shape that becomes the same shape even when rotating at a certain angle.

The preset shape may be circular.

The micro VCSEL chip may be circular and is implemented as a cross section with one portion open.

An area of the first metal layer may be larger than that of an opening.

An area of the second metal layer may be larger than or equal to that of the first metal layer.

The micro VCSEL chip may further include an oxide film layer positioned between the multiple quantum well layer and the first reflector or the second reflector to determine characteristics of a laser to be output and a diameter of the opening.

According to another embodiment of the present invention, a micro VCSEL chip includes a first reflector including a plurality of distributed Bragg reflector (DBR) pairs, a second reflector including a plurality of DBR pairs, a multiple quantum well layer positioned between the first reflector and the second reflector and recombining holes generated from one of the first reflector and the second reflector and electrons generated from the other of the first reflector and the second reflector, a contact layer formed to contact the second reflector, a first metal layer contacting the first reflector to supply power to the first reflector, a second metal layer supplying power to the second reflector, a passivation layer protecting the first reflector, the second reflector, the multiple quantum well layer, the oxide film layer, and the contact layer from an outside, in which the contact layer has a mesa structure only on one side of the micro VCSEL chip.

An area of the first metal layer may be larger than that of an opening.

An area of the second metal layer may be larger than or equal to that of the first metal layer.

According to another embodiment of the present invention, a micro VCSEL chip includes a second reflector including a plurality of DBR pairs, a plurality of multiple quantum well layer positioned between the first reflector and the second reflector and recombining holes generated from one of the first reflector and the second reflector and electrons generated from the other of the first reflector and the second reflector, one or more tunnel junctions formed between the respective multiple quantum well layers, a contact layer formed within one DBR pair of the second reflector, a first metal layer contacting the first reflector and supplying power to the first reflector, a second metal layer contacting the contact layer and supplying power to the second reflector, and a passivation layer protecting the first reflector, the second reflector, the multiple quantum well layer, the oxide film layer, and the contact layer from an outside, in which the contact layer has a mesa structure only on one side of the micro VCSEL chip.

The tunnel junction may connect both adjacent multiple quantum well layers in series.

According to another embodiment of the present invention, a micro VCSEL chip includes a first reflector including a plurality of distributed Bragg reflector (DBR) pairs, a second reflector including a plurality of DBR pairs, a plurality of multiple quantum well layer positioned between the first reflector and the second reflector and recombining holes generated from one of the first reflector and the second reflector and electrons generated from the other of the first reflector and the second reflector, one or more tunnel junctions formed between the respective multiple quantum well layers, a contact layer formed to contact the second reflector, a first metal layer contacting the first reflector and supplying power to the first reflector, a second metal layer contacting the contact layer and supplying power to the second reflector, and a passivation layer protecting the first reflector, the second reflector, the multiple quantum well layer, the oxide film layer, and the contact layer from an outside, in which the contact layer has a mesa structure only on one side of the micro VCSEL chip.

The tunnel junction may connect both adjacent multiple quantum well layers in series.

According to another embodiment of the present invention, a micro VCSEL array includes a substrate, first and second power lines formed on the substrate, an isolator coated on the substrate, the micro VCSEL chip of the micro VCSEL chip, which is disposed and fixed on the isolator, and a first inter connector and a second inter connector electrically connecting each power line to a first metal layer and a second metal layer within the micro VCSEL chip.

### BRIEF DESCRIPTION OF DRAWINGS

FIG. 1 is a cross-sectional view of a micro VCSEL array according to an embodiment of the present invention.

FIG. 2A is a cross-sectional view in one direction of a micro VCSEL according to a first embodiment of the present invention.

FIG. 2B is a cross-sectional view in one direction of a micro VCSEL according to a modification of the first embodiment of the present invention.

FIG. 3 is a diagram illustrating an epitaxial structure of the micro VCSEL according to the first embodiment of the present invention.

FIG. 4A is a cross-sectional view in one direction of a micro VCSEL according to a second embodiment of the present invention.

FIG. 4B is a cross-sectional view in one direction of a micro VCSEL according to a modification of the second embodiment of the present invention.

FIG. 5A is a cross-sectional view in one direction of a micro VCSEL according to a third embodiment of the present invention.

FIG. 5B is a cross-sectional view in one direction of a micro VCSEL according to a modification of the third embodiment of the present invention.

FIG. 6A is a cross-sectional view in one direction of a micro VCSEL according to a fourth embodiment of the present invention.

FIG. 6B is a cross-sectional view in one direction of a micro VCSEL according to a modification of the fourth embodiment of the present invention.

FIG. 7 is a diagram illustrating an epitaxial structure of the micro VCSEL according to the fourth embodiment of the present invention.

FIG. 8A is a schematic plan view of a micro VCSEL in a micro VCSEL array according to each embodiment of the present invention.

FIG. 8B is a schematic plan view of a micro VCSEL in a micro VCSEL array according to modifications of each embodiment of the present invention.

FIG. 9 is a circuit diagram between a switch and a plurality of micro VCSELs according to an embodiment of the present invention.

FIG. 10 is a circuit diagram between a switch and a plurality of micro VCSELs according to another embodiment of the present invention.

### DETAILED DESCRIPTION

Hereinafter, embodiments of the present invention will be described in detail with reference to the accompanying drawings so that those skilled in the art to which the present invention pertains may easily practice the present invention. However, the present invention may be implemented in various different forms, and is not limited to embodiments described herein. In addition, in the drawings, portions unrelated to the description will be omitted to clearly describe the present invention, and similar portions will be denoted by similar reference numerals throughout the specification.

Throughout the present specification, when any part is referred to as being “connected to” another part, it means that any one part and another part are “directly connected to” each other or are “electrically connected to” each other with the other part interposed therebetween. Also, when any part “includes” any component, it means that other components may be further included, rather than excluding other components, unless otherwise stated, and it should be understood that it does not preclude the possibility of addition or presence of one or more other features, numbers, steps, operations, elements, parts, or combinations thereof.

The following embodiments are detailed descriptions for better understanding of the present invention, and do not limit the scope of the present invention. Therefore, the inventions of the same scope that perform the same functions as the present invention will also fall within the scope of the present invention.

In addition, each configuration, process, process, method, etc., included in each embodiment of the present invention may be technically shared within a range that does not contradict each other.

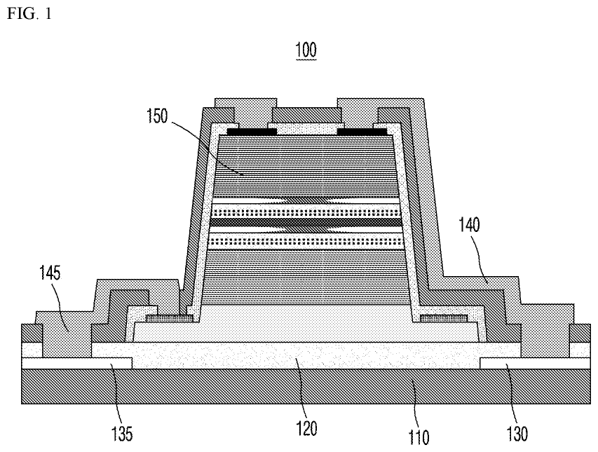

FIG. 1 is a cross-sectional view of a micro VCSEL array according to an embodiment of the present invention.

Referring to FIG. 1, a micro vertical cavity surface emitting laser array (micro VCSEL array) 100 according to an embodiment of the present invention includes a substrate 110, an isolator 120, a first power line 130, a second power line 135, a first inter connector 140, a second inter connector 145, and a micro VCSEL chip 150.

The micro VCSEL array 100 refers to an optical device in which a plurality of micro VCSEL chips 150 are arranged in an array form to vertically output light (or laser) of certain intensity or more. The micro VCSEL array 100 typically includes a plurality of tens to hundreds of micro VCSEL chips 150 to output light of certain intensity or more. The micro VCSEL chip may include one (optical) output unit or may include a plurality of output units. The micro VCSEL chip is illustrated as including one output unit in FIG. 1, but is not necessarily limited thereto.

The substrate 110 supports each component in the micro VCSEL array 100. The substrate 110 may have a flexible characteristic or may have a rigid characteristic.

The isolator 120 is coated on the substrate 110 to prevent the power lines 130 and 135 seated on the substrate 110 from being exposed to the external environment, and enables the micro VCSEL chip 150 to be seated on the substrate 110.

The isolator 120 is coated on the substrate 110 to prevent a surface on which the isolator 120 is coated and components disposed on the substrate with the corresponding surface from being exposed to the external environment. In addition, the micro VCSEL chip 150 to be seated on top thereof and the substrate 110 are separated from each other.

Meanwhile, the isolator 120 is implemented as a component having adhesion while performing the above-described operation, and fixes the micro VCSEL chip 150 to be seated on top thereof. The isolator 120 is made of a polymer or the like to have adhesion, and is adjacent (no direct contact) to an upper portion of the substrate 110 so that the micro VCSEL chip 150 may be bonded and fixed.

The first power line 130 is formed on the substrate 110 to supply power to the micro VCSEL chip 150. The first power line 130 receives power continuously or as needed from an external power source (commercial power supply, battery, etc.). A portion of the first power line 130 is exposed to the outside, and a portion of the upper portion (an opposite direction to a direction toward the substrate) of the first power line 130 of the coated isolator 120 is etched so that the first power line 130 and the first inter connector 140 may be electrically connected. The first power line 130 is electrically connected to the micro VCSEL chip 150 by the first inter connector 140 to supply power to the micro VCSEL chip 150.

The second power line 135 is formed in the same shape as the first power line 130 at a position away from the first power line 130 by a predetermined distance. Since the second power line 135 needs to be electrically connected to another metal layer of the micro VCSEL chip 150 by the second inter connector 145, the second power line 135 is formed at a distance away from the first power line 130 by at least the width of the micro VCSEL chip 150.

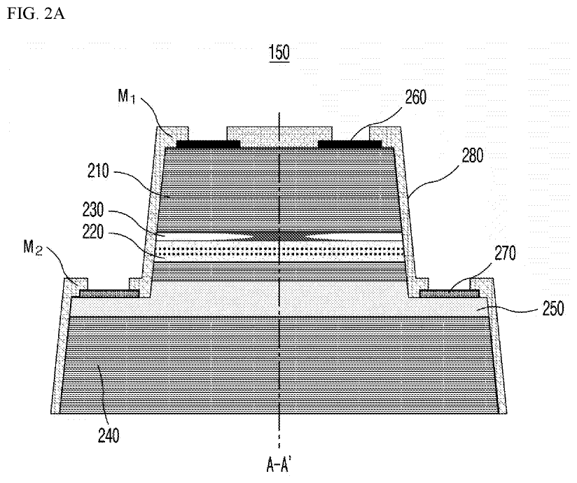

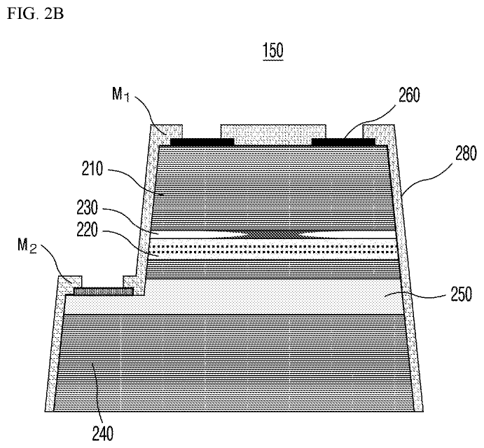

Each inter connector 140 and 145 electrically connects each power line 130 and 135 and each metal layer in the micro VCSEL chip 150. The inter connectors 140 and 145 have one end connected to each power line 130 and 135 via the etched portion of the isolator 120, and the other end connected to each metal layer of the micro VCSEL chip 150 (described later with reference to FIG. 2). Accordingly, each metal layer in the micro VCSEL chip 150 may receive power from the outside.

The micro VCSEL chip 150 receives power and oscillates light or laser. The micro VCSEL chip 150 is seated on the isolator 120 and oscillates light or laser in the opposite direction where the substrate 110 is located. The micro VCSEL chip 150 may include one (optical) output unit (emitter) or may include a plurality of output units. In addition, when the micro VCSEL chip 150 includes a plurality of output units, all of the output units may output light of the same wavelength band or some or all of the output units may output light of different wavelength bands. A specific structure of the micro VCSEL chip 150 will be described later with reference to FIGS. 2 to 8.

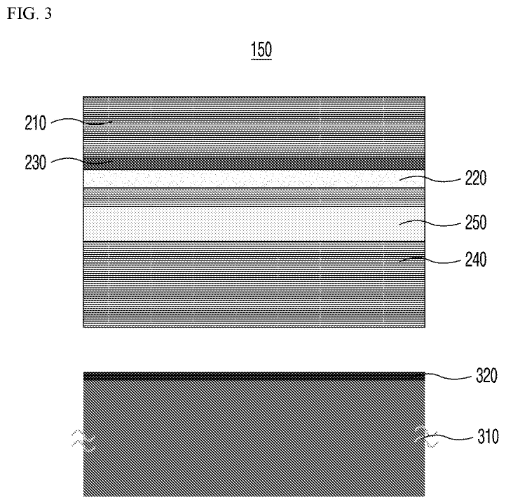

FIG. 2A is a cross-sectional view in one direction of a micro VCSEL according to a first embodiment of the present invention, FIG. 2B is a cross-sectional view in one direction of a micro VCSEL according to a modification of the first embodiment of the present invention, and FIG. 3 is a diagram illustrating an epitaxial structure of the micro VCSEL according to the first embodiment of the present invention.

Referring to FIGS. 2A and 3, the micro VCSEL chip 150 according to an embodiment of the present invention includes a first reflector 210, a multiple quantum well layer 220, an oxide film layer 230, a second reflector 240, a first contact layer 250, an etch stop layer, a first metal layer 260, a second metal layer 270, and a passivation layer 280.

The first reflector 210 may be made of a semiconductor material doped with a p-type dopant, and may be made of AlGaAs, which is a semiconductor material containing Al. The first reflector 210 is composed of a plurality of distributed Bragg reflector (DBR) pairs. The plurality of DBR pairs are implemented with a high aluminum (Al) composition layer including a high aluminum (Al) ratio of 85 to 100% and a low Al composition layer including a low aluminum ratio of 0 to 20% as one pair. The first reflector 210 includes a smaller number of DBR pairs than the second reflector 240 and has relatively lower reflectance. Accordingly, light or laser to be oscillated from the multiple quantum well layer 220 is oscillated in the direction of the first reflector 210 having a relatively low reflectance due to a relatively small number of pairs.

The ratio of aluminum included in the high Al composition layer of the first reflector 210 is formed to be relatively lower than that of the second reflector 240. Accordingly, each reflector in the micro VCSEL chip 150 according to an embodiment of the present invention may maintain the same reflectivity, but the overall thickness of the micro VCSEL chip 150 may be reduced compared to the related art.

The multiple quantum well layer (MQW) 220 is a layer in which holes generated from the first reflector 210 and electrons generated from the second reflector 240 meet and recombine. Holes and electrons recombine in the multiple quantum well layer 220 to emit light. The multiple quantum well layer 220 has a structure in which well layers (not shown) and barrier layers (not illustrated) having different energy bands are alternately stacked once or more. The well layer (not illustrated)/barrier layer (not illustrated) of the multiple quantum well layer 220 may be made of InGaAs/AlGaAs, InGaAs/GaAs, GaAs/AlGaAs, or the like.

The oxide film layer 230 includes an oxidized portion of a certain length by an oxidation process, and determines characteristics of an output laser and a diameter of an opening according to the length of the oxidized portion. The oxide film layer 230 is made of aluminum (Al) having a higher concentration than the first reflector 210 and the second reflector 240. The higher the aluminum concentration, the higher the rate at which it is oxidized. As the oxide film layer 230 is implemented with a relatively higher aluminum concentration than both the reflectors 210 and 240, in the subsequent oxidation process, oxidation may be selectively performed. For example, the oxide film layer 230 may be made of AlGaAs having an Al ratio of 98% or more, and each reflector 210 and 240 may be made of AlGaAs having an Al ratio between 0% and 100%. In FIG. 2, the oxide film layer 230 is illustrated as being formed at a position adjacent to the first reflector 210, but is not necessarily limited thereto, and may be formed at a position adjacent to the second reflector 240 or at both positions adjacent to the first reflector 210 and the second reflector 240.

The second reflector 240 may be implemented as an n-type semiconductor layer doped with an n-type dopant, and may be made of AlGaAs, which is a semiconductor material containing Al. The second reflector 240 is similarly composed of a plurality of DBR pairs. However, as described above, the second reflector 240 has relatively high reflectance because it includes a relatively larger number of DBR pairs than the first reflector 210. Accordingly, the light or laser to be oscillated from the cavity layer is oscillated in the direction of the first reflector 210 having a relatively low reflectance due to a relatively small number of pairs.

Meanwhile, the first contact layer 250 is formed on the low Al composition layer in one DBR pair of the second reflector 240. As the first contact layer 250 is formed in the second reflector 240, the micro VCSEL chip 150 may have an intra VCSEL structure. The first contact layer 250 is formed on the low Al composition layer, but unlike the low aluminum component layer, may be implemented as a GaAs component. However, these components have a property of absorbing some of the oscillated light or laser. Accordingly, the first contact layer 250 is formed at a position away from the multiple quantum well layer 220 by a predetermined distance. As the first contact layer 250 is away from the multiple quantum well layer 220 by a predetermined distance, the micro VCSEL chip 150 may minimize light or laser absorption while having the intra VCSEL structure. Here, the predetermined distance may be a position away from the multiple quantum well layer 220 by a plurality of pairs (high Al composition layer and low Al composition layer), in particular, 4 to 5 pairs. As the first contact layer 250 is formed at a position away from the multiple quantum well layer 220 by a predetermined distance, it may have the above-described features.

The first contact layer 250 has a relatively thick thickness that has m times a thickness of one DBR pair. Accordingly, the first contact layer 250 may allow the micro VCSEL chip 150 to have a mesa structure M₂ while allowing the second reflector 240 to be connected to the second metal layer 270. As the first contact layer 250 has a relatively thick thickness, etching may occur up to one position in a height direction of the first contact layer 250 without difficulty. Accordingly, the micro VCSEL chip 150 has a mesa structure M₂. In addition, the etching occurs up to one position of the first contact layer 250, and the first contact layer 250 is exposed to the outside, so the second metal layer 270 may be disposed on the exposed portion.

The first metal layer 260 contacts the first reflector 210 so that power may be supplied to the first reflector 210. The first metal layer 260 may be a p-metal such as titanium (Ti), platinum (Pt), or gold (Au). As the first metal layer 260 is formed on the top of the first reflector 210 (based on FIG. 2), power applied through the second inter connector 145 is transferred to the first reflector 210.

The second metal layer 270 contacts the first contact layer 250 so that power may be supplied to the second reflector 240. Unlike the first metal layer 260, the second metal layer 270 may be an n-metal. The micro VCSEL chip 150 has a shape etched into the mesa structure M₂ from the first reflector 210 to a position of the first contact layer 250. By this etching, a portion of the first contact layer 250 is exposed to the outside, and the second metal layer 270 is disposed at the exposed position of the first contact layer 250. As the second metal layer 270 is formed on the top of the second reflector 240 and the top of the first contact layer (based on FIG. 2), power applied through the first inter connector 140 is transferred to the second reflector 240.

However, polarities of the first metal layer 260 and the second metal layer 270 and polarities of the inter connectors 140 and 145 and each power lines 130 and 135 connected accordingly may be changed.

The micro VCSEL chip 150 has a plurality of mesa structures. The micro VCSEL chip 150 is etched into the mesa structure M₂ up to one position of the first contact layer 250 to have two mesa structures.

The passivation layer 280 is applied to side surfaces of components other than a portion of the first metal layer 260, a portion of the second metal layer 270, and each metal layer to protect each component from the outside.

The components of the micro VCSEL chip 150 described above are grown on the substrate 310, and a sacrificial layer 320 is grown between the components of the micro VCSEL chip 150 and the substrate 310. The sacrificial layer 320 is etched by an etchant to separate the substrate 310 and the micro VCSEL chip 150.

By having such a structure, the micro VCSEL chip 150 becomes easy to transfer to the substrate.

Meanwhile, referring to FIG. 2B, the micro VCSEL chip 150 includes the same components as those of the micro VCSEL chip 150 illustrated in FIG. 2A.

However, the first contact layer 250 may have the mesa structure M₂ only on one side of the micro VCSEL chip 150. That is, as described above, etching for the first contact layer 250 to have the mesa structure M₂ may be performed on only one side of the micro VCSEL chip 150. This may bring about the following effects. As described above, when the first contact layer 250 has the mesa structure and the second metal layer 270 is disposed, even if the passivation layer 280 is applied to the mesa structure of the first contact layer 250 on which the second metal layer 270 is not disposed, the second inter connector 145 is disposed on the corresponding portion. Although not directly electrically connected, crossing the second inter connector 145 on the first contact layer 250 or the second reflector 240 applied with power of a specific polarity by the first metal layer 260 may cause electrical noise. This may cause deterioration in beam quality of the micro VCSEL chip 150.

To solve the problem, the first contact layer 250 may have the mesa structure M₂ only on one side of the micro VCSEL chip 150. The second metal layer 270 is disposed only on the first contact layer 250 having the mesa structure, and the second metal layer 270 and the second inter connector 145 may be connected. Accordingly, as described above, even if the first inter connector 140 is formed on the opposite side thereof, no exposed portion of the first contact layer 250 may exist. Accordingly, electrical noise may be prevented from deteriorating the beam quality of the micro VCSEL chip 150.

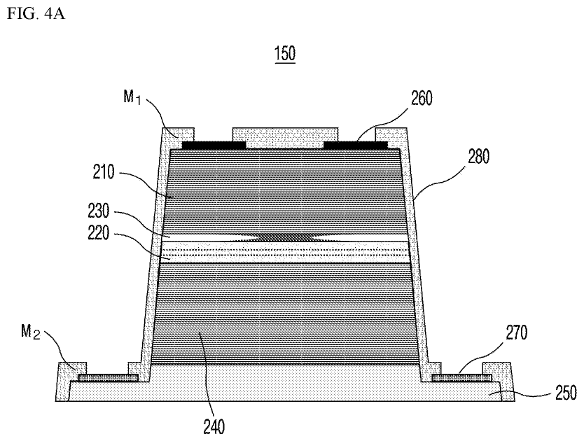

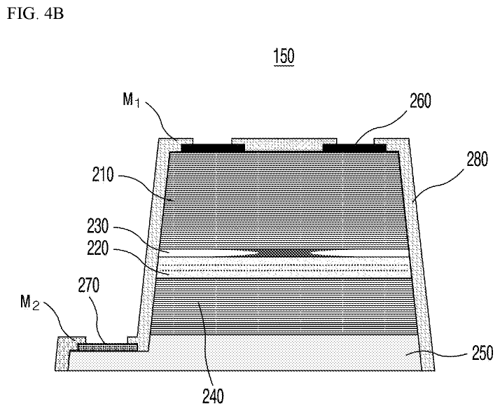

FIG. 4A is a cross-sectional view in one direction of a micro VCSEL according to a second embodiment of the present invention and FIG. 4B is a cross-sectional view in one direction of a micro VCSEL according to a modification of the second embodiment of the present invention.

Referring to FIG. 4A or 4B, the micro VCSEL chip 150 according to the second embodiment or a modification of the second embodiment of the present invention has the same components as those of the micro VCSEL chip 150 according to the first embodiment or a modification of the first embodiment, but may be implemented with a different structure.

The first contact layer 250 in the micro VCSEL chip 150 according to the first embodiment or a modification of the first embodiment is formed on the low Al composition layer in one DBR pair of the second reflector 240, and the micro VCSEL chip 150 according to the first embodiment has an intra VCSEL structure.

On the other hand, the micro VCSEL chip 150 according to the second embodiment or the modification of the second embodiment has a structure in which the first contact layer 250 is formed on the bottom of the second reflector 240 instead of the inside of the second reflector 240. Accordingly, the micro VCSEL chip 150 similarly has a plurality of mesa structures, but does not have the intra VCSEL structure.

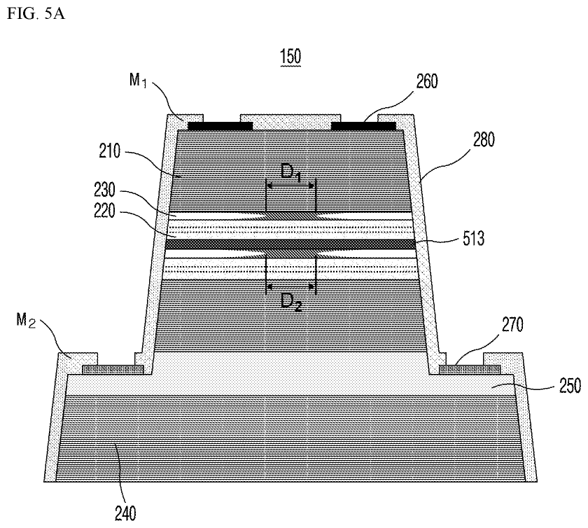

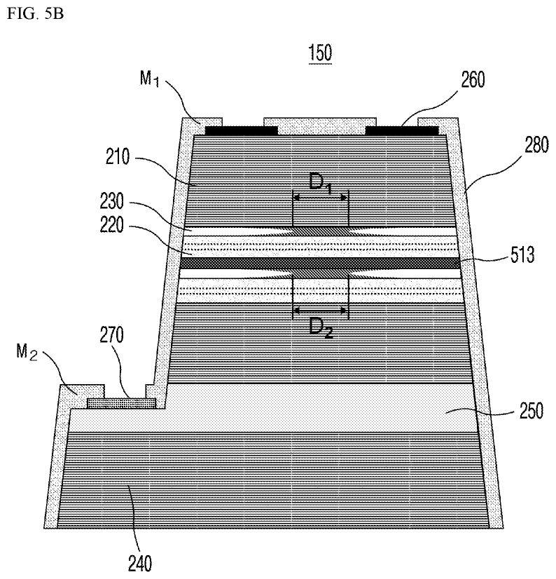

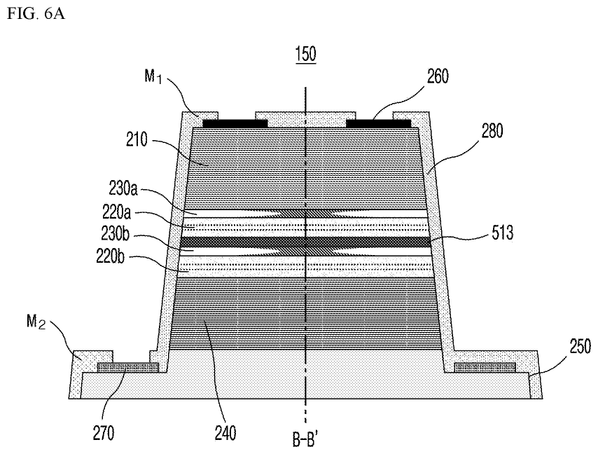

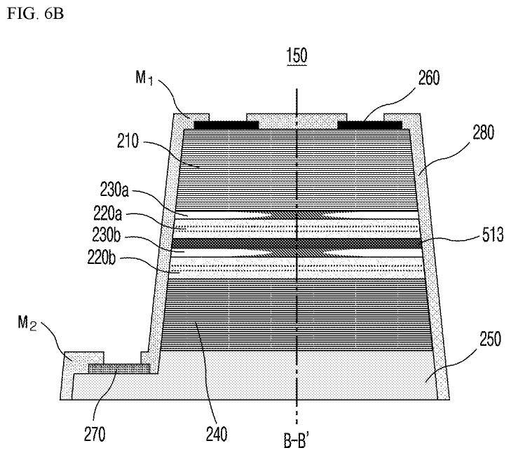

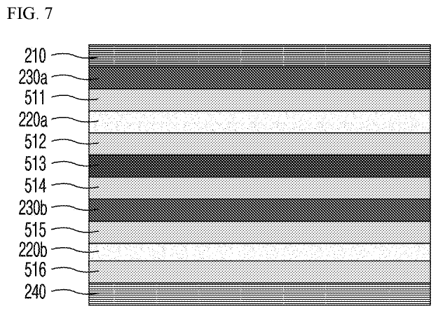

FIG. 5A is a cross-sectional view in one direction of a micro VCSEL according to a third embodiment of the present invention, FIG. 5B is a cross-sectional view in one direction of a micro VCSEL according to a modification of the third embodiment of the present invention, FIG. 6A is a cross-sectional view in one direction of a micro VCSEL according to a fourth embodiment of the present invention, FIG. 6B is a cross-sectional view in one direction of a micro VCSEL according to a modification of the fourth embodiment of the present invention, and FIG. 7 is a cross-sectional view of a micro VCSEL in another direction according to the fourth embodiment of the present invention.

Referring to FIGS. 5 to 7, the micro VCSEL chip 150 according to the third/fourth embodiment or modifications of each embodiment have the same structure as the micro VCSEL chip 150 according to the first/second embodiment or modifications of the corresponding embodiment, respectively, but includes a plurality of multiple quantum well layers 220, one or more tunnel junctions 513, one or more p-cavity layers (or p-type layers, 511, 514, and 515) and one or more n-cavity layers (or an n-type layers 512 and 516). Furthermore, the micro VCSEL chip 150 may further include one or more oxide film layers 230.

The micro VCSEL chip 150 includes the plurality of multiple quantum well layers 220 and one or more tunnel junctions 513 formed between the respective multiple quantum well layers. The tunnel junction 513 serves to connect the multiple quantum well layers 220 adjacent thereto in series. Accordingly, even when a relatively low current power is input as a short pulse, a relatively high output light or laser may be oscillated.

Assuming that the first metal layer 260 is implemented as an anode and the second metal layer 270 is implemented as a cathode, a p-cavity layer 511 may be disposed between an oxide film layer 230a and a multiple quantum well layer 220a, an n-cavity layer 512 may be disposed between the multiple quantum well layer 220a and the tunnel junction 513, a p-cavity layer 514 may be disposed between the tunnel junction 513 and an oxide film layer 230b, a p-cavity layer 515 may be disposed between the oxide film layer 230b and the multiple quantum well layer 220b, and an n-cavity layer 516 may be disposed between the multiple quantum well layer 220b and the second reflector 240. Each cavity layer surrounds multiple quantum well layer 220 or other layers and provides feedback of laser light.

Meanwhile, when the plurality of oxide film layers 230a and 230b are included, an area of an opening D₂ of the oxide film layer 230b located close to the substrate should be formed to be larger than that of an opening D₁ of the oxide film layer 230a located far from the substrate. When the area of the opening D₂ of the oxide film layer 230b is formed to be smaller than that of the opening D₁ of the oxide film layer 230a, a problem occurs in that beam characteristics of oscillating light or laser deteriorate. Accordingly, when the plurality of oxide film layers 230a and 230b are included, the areas of the openings D₁ and D₂ satisfy the above-described conditions.

However, FIG. 5 illustrates that the micro VCSEL chip 150 necessarily includes the plurality of oxide film layers 230a and 230b, but it is not necessarily limited thereto. Any one or all of the oxide film layers 230 may be implemented as adjacent p-cavity layers 511 or 514/515. The oxide film layer 230a is implemented as one p-cavity layer 511 and may be excluded from the micro VCSEL chip 150, and the oxide film layer 230b forms one p-cavity layer 514 and 515 and may be excluded from the micro VCSEL chip 150.

As such, the micro VCSEL chip 150 may include the plurality of multiple quantum well layers 220 and one or more tunnel junctions 513 formed between the respective multiple quantum well layers.

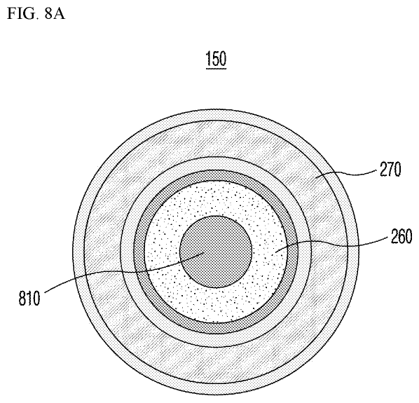

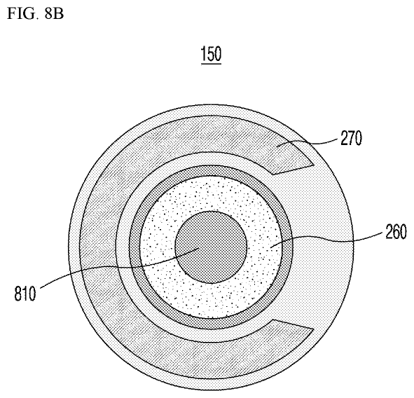

FIG. 8A is a schematic plan view of a micro VCSEL in a micro VCSEL array according to each embodiment of the present invention.

Referring to FIG. 8A, the micro VCSEL chip 150 is implemented as a cross section of a predetermined shape. Here, the predetermined shape refers to a shape that becomes the same shape even when rotating at a certain angle, and for example, there is a circular shape.

Also, an area of an opening 810 of the micro VCSEL chip 150 is smaller than that of the first metal layer 260, and the area of the first metal layer 260 is formed to be smaller than that of the second metal layer 270.

As the micro VCSEL chip 150 satisfies the above-described conditions, even if a shift occurs in the x, y, and el directions during the transfer to the substrate 110 after manufacturing the micro VCSEL chip 150, the resulting efficiency degradation may be minimized. The position of the micro VCSEL chip 150 in the micro VCSEL array 100 may be different from the planned position during the transfer, but the positions of the substrate 110 and the inter connectors 140 and 145 do not differ from the planned positions.

Therefore, even if the micro VCSEL chip 150 moves in any direction of the x-axis direction and the y-axis direction from the planned position during the transfer, it needs to be able to contact each of the inter connectors 140 and 145. To solve this problem, as described above, the area of the first metal layer 260 is implemented to be relatively larger than that of the opening 810, and the area of the second metal layer 270 is implemented to be larger than that of the first metal layer 260. As the areas of the first metal layer 260 and the second metal layer 270 are implemented to be relatively larger, even if the micro VCSEL chip 150 moves in any direction of the x-axis direction and the y-axis direction from the planned position, it may contact each inter connect 140 and 145.

In addition, even if the micro VCSEL chip 150 rotates in an arbitrary el axis from a planned direction during the transfer, it needs to be able to contact each inter connectors 140 and 145. Since the micro VCSEL chip 150 is implemented in a shape independent of the direction, the first metal layer 260 and the second metal layer 270 do not have directionality, so even if the micro VCSEL chip 150 rotates, it may contact each inter connector 140 and 145.

FIG. 8B is a schematic plan view of a micro VCSEL in a micro VCSEL array according to modifications of each embodiment of the present invention.

Referring to FIG. 8B, the micro VCSEL chip 150 is implemented as a cross section of a predetermined shape. Here, the predetermined shape refers to a shape that becomes the same shape even when rotating within a predetermined angular range, and for example, there is a circular shape.

Since the second metal layer 270 is not be disposed on a portion of the first contact layer in which the mesa structure is not formed, it is implemented as a cross section having the predetermined shape (circular shape) with one portion open.

Also, the area of an opening 810 of the micro VCSEL chip 150 is smaller than that of the first metal layer 260, and the area of the first metal layer 260 is formed to be smaller than or equal to that of the second metal layer 270. For the reason described above, the area of the second metal layer 270 may be larger than or equal to that of the first metal layer 260.

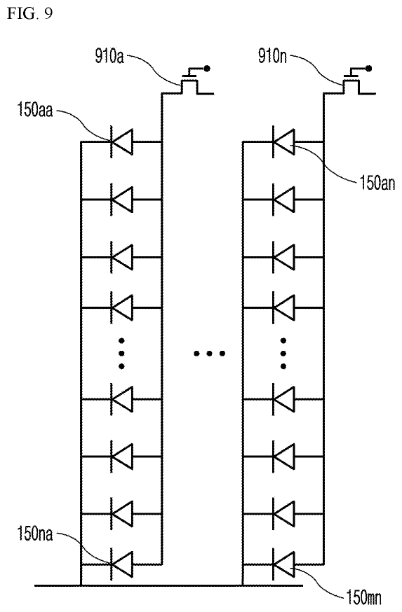

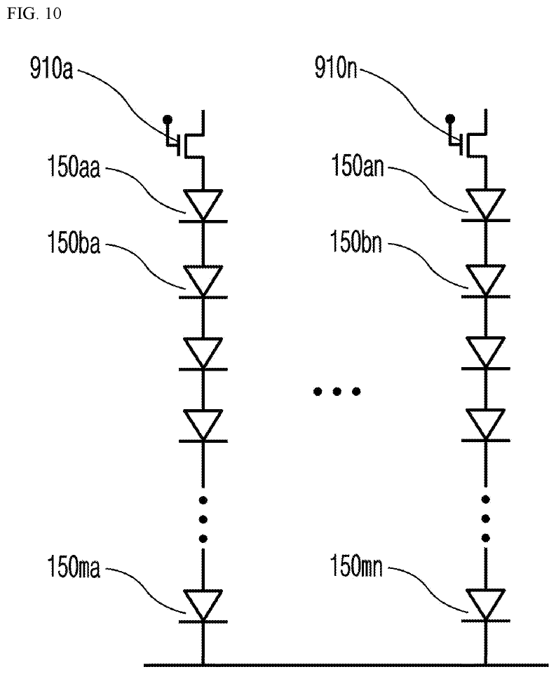

FIG. 9 is a circuit diagram between a switch and a plurality of micro VCSELs according to an embodiment of the present invention, and FIG. 10 is a circuit diagram between a switch and a plurality of micro VCSELs according to another embodiment of the present invention.

The micro VCSEL chips 150 in the micro VCSEL array 100 may be connected in parallel as illustrated in FIG. 9. The VCSELs of each column are connected in parallel with each other, and each micro VCSEL chip (connected in parallel) is connected to a switch 910 on one side and to a ground terminal (not illustrated) on the other side. Accordingly, when the switch 910 is short-circuited and power is supplied to one side of the micro VCSEL chips, all the micro VCSEL chips in the column may operate.

Since the micro VCSEL chips in each column are connected in parallel, a significant amount of current may need to be transferred in order for the micro VCSEL chips in the column to operate. Accordingly, the switch 910 may solve this problem as it is implemented as a GaN FET.

Meanwhile, the micro VCSEL chips 150 in the micro VCSEL array 100 may be connected in series as illustrated in FIG. 10. When each of the micro VCSEL chips 150 are connected in series, unlike the case where they are connected in parallel, excessive current does not need to flow on the array, and the amount of current flowing through the micro VCSEL chip 150 may not change due to the difference in internal resistance.

As described above, according to one aspect of the present invention, it is possible to improve manufacturing efficiency, minimize efficiency degradation due to errors occurring during a transfer, and improve beam quality of light or laser to be oscillated.

The spirit of the present embodiment is illustratively described hereinabove. It will be appreciated by those skilled in the art to which the present embodiment pertains that various modifications and alterations may be made without departing from the essential characteristics of the present embodiment. Accordingly, the present embodiments are not to limit the spirit of the present embodiment, but are to describe the spirit of the present embodiment. The technical idea of the present embodiment is not limited to these embodiments. The scope of the present embodiment should be interpreted by the following claims, and it should be interpreted that all the spirits equivalent to the following claims fall within the scope of the present embodiment.

What is claimed is:

1. A micro VCSEL chip, comprising:
a first reflector including a plurality of distributed Bragg reflector (DBR) pairs;
a second reflector including a plurality of DBR pairs;
a multiple quantum well layers positioned between the first reflector and the second reflector and recombining holes generated from one of the first reflector and the second reflector and electrons generated from the other of the first reflector and the second reflector;
a contact layer formed within one DBR pair of the second reflector or formed to contact the second reflector;
a first metal layer contacting the first reflector and supplying power to the first reflector;
a second metal layer contacting the contact layer and supplying power to the second reflector; and
a passivation layer protecting the first reflector, the second reflector, the multiple quantum well layers, and the contact layer from an outside.

2. The micro VCSEL chip of claim 1, wherein the micro VCSEL chip is implemented as a cross section of a predetermined shape.

3. The micro VCSEL chip of claim 2, wherein the predetermined shape is a shape that becomes the same shape even when rotating at a certain angle.

4. The micro VCSEL chip of claim 1, wherein the contact layer has a mesa structure only on one side of the micro VCSEL chip.

5. The micro VCSEL chip of claim 2, wherein an area of the first metal layer is larger than that of an opening.

6. The micro VCSEL chip of claim 1, wherein an area of the second metal layer is larger than or equal to that of the first metal layer.

7. A micro VCSEL chip, comprising:
a first reflector including a plurality of distributed Bragg reflector (DBR) pairs;
a second reflector including a plurality of DBR pairs;
a plurality of multiple quantum well layers positioned between the first reflector and the second reflector and recombining holes generated from one of the first reflector and the second reflector and electrons generated from the other of the first reflector and the second reflector;
one or more tunnel junctions formed between the respective multiple quantum well layers;
a contact layer formed within one DBR pair of the second reflector or formed to contact the second reflector;
a first metal layer contacting the first reflector and supplying power to the first reflector;
a second metal layer contacting the contact layer and supplying power to the second reflector; and
a passivation layer protecting the first reflector, the second reflector, the multiple quantum well layers, and the contact layer from an outside.

8. The micro VCSEL chip of claim 7, wherein the contact layer has a mesa structure only on one side of the micro VCSEL chip.

9. The micro VCSEL chip of claim 7, wherein the tunnel junction connects both adjacent multiple quantum well layers in series.

10. A micro VCSEL array, comprising:
a substrate;
first and second power lines formed on the substrate; an isolator coated on the substrate;
the micro VCSEL chip of claim 1, which is disposed and fixed on the isolator; and
a first inter connector and a second inter connector electrically connecting each power line to the first metal layer and the second metal layer within the micro VCSEL chip.
